(19) United States
(12) Patent Application Publication
(10) Pub. No.: US 2003/0025182 A1
(43) Pub. Date: Feb. 6, 2003

(54) Metal article coated with tin or tin alloy under tensile stress to inhibit whisker growth

(76) Inventors: Joseph A. Abys, Warren, NJ (US); Chonglun Fan, Bridgewater, NJ (US); Chen Xu, New Providence, NJ (US); Yun Zhang, Warren, NJ (US)

Correspondence Address: Glen E. Books, Esq., Lowenstein Sandler, 65 Livingston Avenue, Roseland, NJ, 07068, US

(21) Appl. No.: 09/887,827

(22) Filed: Jun. 22, 2001

(51) Int. Cl. H01L 23/495

(52) U.S. Cl. 257/666; 257/677

(57) ABSTRACT

In accordance with a first aspect of the invention, a metal substrate is provided with a layer of tin or tin alloy that is coated under tensile stress to inhibit the growth of tin whiskers. The tensile stressed tin and tin alloy is preferably coated with a grain size larger than 1 micrometer. Advantageously the tin or tin alloy is coated on an underlayer chosen to maintain or generate the tensile stress state in the tin coating. The tensile stress inhibits whisker growth, and the resulting structure is particularly useful as a part of an electrical connector or lead frame. In a second aspect of the invention, the tensile stress of tin coatings is monitored to provide coatings of reduced tendency toward whisker growth.

### FIELD OF THE INVENTION

This invention relates to metal articles coated with tin or tin alloy for solderability and protection from corrosion. In particular, it concerns an article having a finish comprising a layer of tin or tin alloy that is under tensile stress to inhibit the growth of tin whiskers. The surface finish is especially useful for electrical connectors and integrated circuit lead frames.

### BACKGROUND OF THE INVENTION

High quality connectors are increasingly important in a wide variety of products including consumer electronics, household appliances, computers, automobiles, telecommunications, robotics and military equipment. Connectors provide the paths whereby electrical current flows from one device to another. Quality connectors should be highly conductive, corrosion resistant, wear resistant, readily connected by solder and inexpensive.

Unfortunately no single material has all the desired characteristics. Copper and many of its alloys are highly conductive, but they are subject to corrosion in typical ambients, producing reactive oxides and sulfides. The reactive corrosion products reduce the conductivity of the connectors and the reliability of interconnection. The corrosion products also interfere with the formation and reliability of solder bonds and can migrate to other electronic components which they adversely affect.

Thin layers of tin have been applied to copper surfaces to provide corrosion resistance and solderability. Tin is easily applied, non-toxic, provides corrosion protection and has excellent solderability. Unfortunately tin coatings are subject to spontaneous growth of metallic filaments called tin “whiskers”. These whiskers have been identified as a cause of short circuit failures in low voltage equipment. Moreover whisker fragments can detach and accumulate within device packages, causing shorts at locations remote from their origin. Accordingly, it would be advantageous to provide metal articles with whisker free coatings of tin.

### SUMMARY OF THE INVENTION

In accordance with a first aspect of the invention, a metal substrate is provided with a layer of tin or tin alloy that is coated under tensile stress to inhibit the growth of tin whiskers. The tensile stressed tin and tin alloy is preferably coated with a grain size larger than 1 micrometer. Advantageously the tin or tin alloy is coated on an underlayer chosen to maintain or generate the tensile stress state in the tin coating. The tensile stress inhibits whisker growth, and the resulting structure is particularly useful as a part of an electrical connector or lead frame. In a second aspect of the invention, the tensile stress of tin coatings is monitored to provide coatings of reduced tendency toward whisker growth.

### BRIEF SUMMARY OF THE DRAWINGS

The advantages, nature and various additional features of the invention will appear more fully upon consideration of the illustrative embodiments now to be described in detail in connection with the accompanying drawings:

FIG. 1 is a schematic cross section of a metal article coated in accordance with the invention;

FIG. 2 is a block diagram showing the steps involved in making the coated metal article of FIG. 1;

FIG. 3 shows a substrate for making an electrical connector using the process of FIG. 2;

FIG. 4 shows a substrate for making an integrated circuit lead frame.

FIGS. 5A, 5B, 5C and 5D show focused ion beam (FIB) images of a tin whisker found on a matte Sn surface;

FIG. 6 shows FIB images of a tin whisker found on a satin bright Sn surface; and

FIGS. 7A, 7B and 7C show FIB images of a tin whisker found on a bright Sn surface with successively increasing magnification.

It is to be understood that these drawings are for purposes of illustrating the concepts of the invention and are not to scale.

### DETAILED DESCRIPTION

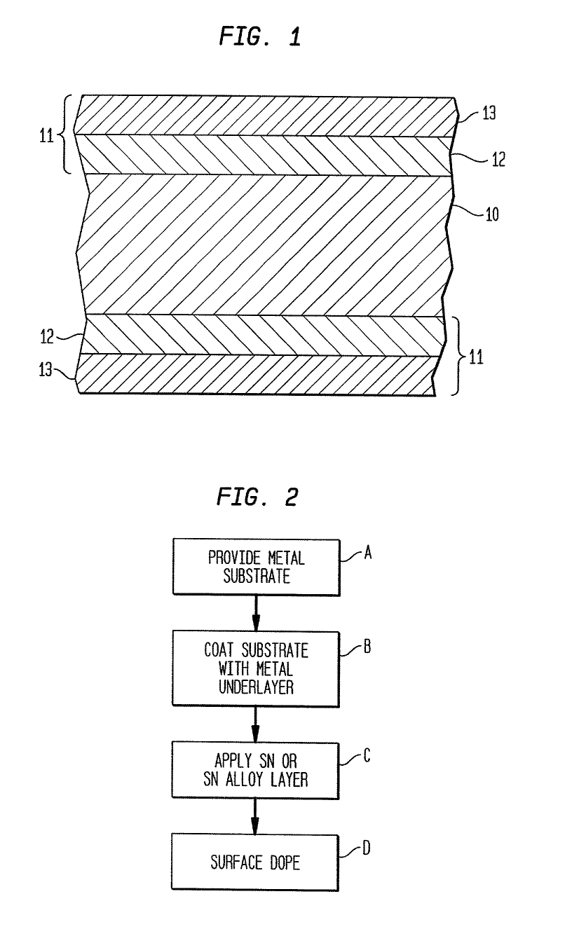

FIG. 1 is a schematic cross section of a metal substrate 10 coated with a finish 11 including an optional metal underlayer 12 and a layer 13 of tin or a tin alloy under tensile stress to inhibit whisker formation. Specifically the tin or tin alloy is under tensile stress in excess of 2 MPa and preferably in excess of 3 MPa. Advantageously the tin or tin alloy is coated with a mean grain size exceeding one micrometer and preferably exceeding 2 microns and even more preferably exceeding 3 microns. The metal substrate 10 is typically a conductive metal such as copper, copper alloy, iron or iron alloy subject to corrosion in typical ambients. The optional underlayer 12 is advantageously a coating such as nickel, nickel alloy, cobalt or cobalt alloy, or iron or iron alloy chosen to maintain or generate the tensile stress in the layer of tin or tin alloy. In substrates comprising copper or iron the underlayer 12 can be nickel. Nickel-phosphorus-tungsten or cobalt-phosphorus can also be used. The layer 13 can be tin or a tin alloy usually subject to whisker growth such as tin-copper, tin-bismuth, tin-bismuth-silver, tin-silver, tin-nickel, tin-zinc or tin-copper-silver. The optional underlayer 12 can have a thickness in the range of 0-20 μm. The layer 13 typically has a thickness in the range 0.5-10 μm.

The layer 13 is advantageously plated under tensile stress by choice of the plating chemistry and substrate. Tin-based layers are ordinarily deposited with low stress. On copper, the layers are typically under compressive stress. Choice of a proper substrate and chemistry permits plating with a tensile stress and preferably greater than 2˜3 MPa. Choice of chemistry, including the omission of the usual grain refiners, permits plating of tin-based layers with large grain size with a mean effective diameter greater than about 1 micrometer.

The invention can now be understood more clearly by consideration of the following specific examples describing the fabrication and inspection of coated metal articles in accordance with the invention.

### EXAMPLE 1

### Electrical Connector

FIG. 2 is a block diagram of the steps in making a coated metal electrical connector. The first step, shown in Block A, is to provide a metal substrate. The substrate can be formed into a desired configuration as by stamping or etching a metal blank.

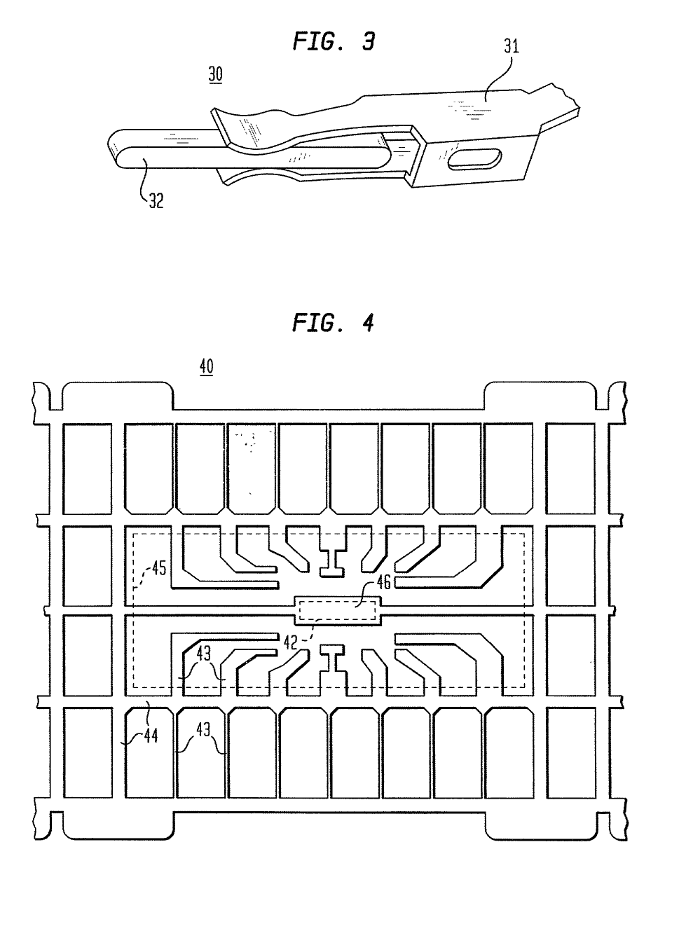

FIG. 3 illustrates a substrate for an electrical connector 30 having a connector body 31 and a mating pin 32. The connector 31 and the pin 32 are made of high conductivity metal such as copper-nickel-tin alloy No. 725 (88.2 wt. % Cu, 9.5 Ni, 2.3 Sn; ASTM Spec. No. B122).

The next step, which is optional, is to coat the conductive substrate 10 with a metal underlayer 12 such as nickel. The underlayer 12 can have a thickness from 0 to about 5 μm. A suitable nickel underlayer can be electrodeposited using the following bath composition:

A suitable Ni-chemistry would be:

| | |
|---|---|
| Ni sulfamate: | 319-383 g/l |
| NiCl₂ * 6 H₂O: | 5-15 g/l |
| H₃BO₃: | 20-40 g/l |
| Sodium Lauryl Sulfate: | 0.2-0.4 g/l |
| pH: | 2.0-2.5 |
| T: | 55-65° C. |
| CD: | 20-300 ASF |

The third step, Block C, is to apply a layer 13 of tin or tin alloy under tensile stress. The layer 13 should have a thickness greater than about 0.5 μm and is preferably about 3 μm. It should have an average grain size greater than about 1 micrometer. A suitable tin layer can be electrodeposited under tensile stress using the following bath conditions:

| | |
|---|---|
| Tin methane sulfonate | 40-80 g/l |
| Methane sulfonic acid | 100-200 g/l |
| Wetting Agent 300 | 5-15 g/l |
| (Lucent ECS) | |
| Anti-Oxidant C1 | 1-3 g/l |
| (Lucent ECS) | |
| Temperature | 50° C. |
| CD | 100 ASF |
| pH | about 0 |

After aging at RT for 4 months, the stress is about 7 MPa. No whisker was observed.

### EXAMPLE 2

### Integrated Circuit Lead Frame

An integrated circuit lead frame can also be fabricated by the process illustrated in FIG. 2. The only differences are that the substrate is different and the tin coating thickness can be greater (e.g. 0.5-15 μm).

FIG. 4 illustrates a substrate 40 formed into configuration for use as a lead frame for an integrated circuit (IC). The substrate 40 includes a paddle 42 on which the IC is to be mounted and the leads 43 on which the IC is to be bonded. Dam bars 44 interconnect the leads before packaging. After the integrated circuit is bonded and a packaging medium has been applied over an area shown in phantom lines 45, the dam bars 44 are trimmed away.

The substrate of the lead frame can be copper or a copper alloy such as alloy No. 151 (99.9 wt. % Cu, 0.1% Zr) or alloy No. 194 (97.5 wt. % Cu, 2.35% Fe, 0.03% P, 0.12% Zn). Other conductive metals and alloys such as alloy No. 42 (42 wt. % Ni, 58% Fe) can also be used.

An integrated circuit 46 is mounted and bonded to the substrate and the substrate is coated by the process illustrated in FIG. 2. The result is an IC lead frame including a surface finish comprising surface doped tin or tin alloy.

### EXAMPLE 3

### Inspection

In accordance with a second aspect of the invention one can monitor or inspect a deposited tin or tin alloy coating for tendency to grow tin whiskers by measuring the internal stress in the coating. Such measurement can be effected, for example, by x-ray diffraction to measure the change in the lattice constant due to stress. The stress can then be calculated from the change in lattice constant. The coating can then be accepted or rejected based on whether the tensile stress exceeds a specified value, typically about 2 MPa and preferably about 3 MPa.

The stress can be measured using conventional x-ray diffraction equipment such as D8 Discover Diffractometer System with GADDS marketed by Brucker Analytical X-Ray Systems, Inc. Cr-radiation can be used to achieve high accuracy lattice constant measurement for Ψ angles from −45° to 45° for the diffraction peak (312) at 2θ=143.8°. The stress in the coating can then be calculated using the sin²Ψ plot method. Advantageously continuous scan or stage oscillation is used in scanning large-grain samples such as matte and satin bright tin.

### EXPERIMENTAL VERIFICATION

Applicants have examined the effect of the stress on the whisker growth kinetics. Sn plated directly over Cu substrate was subjected to tensile or compressive external stress. The whisker index, calculated from the density and size of the whiskers, was determined at various stages of thermal aging at 50° C. This result is summarized in Table 1.

TABLE 1
Effect of the Stress on the Whisker Growth Kinetics

| Whisker index | | | | Length |
|---|---|---|---|---|
| Finish | 4 Months | 6 months | 9 months | Longest* |
| Bright | 279 | 13,000 | 63,400 | 600 |
| Bright + Tensile | 244 | 2,800 | 45,200 | 350 |
| Bright + Compressive | 3850 | 13,500 | 193,000 | 750 |

*Longest whisker observed up to 9 months in μm

As it can be clearly seen from Table 1, the compressive stress promotes the whisker growth. The sample under tensile stress, however, shows a smaller whisker index and shorter whisker length compared to the sample, which is not under external stress. This result suggests that the tensile stress slows down the whisker growth.

To review the local structure of whiskers, cross sections along the root of the whisker were made using focused ion beam (FIB). In a FIB experiment, an extremely small diameter beam of gallium ions is used to image the surface and locate the whisker. The same focused ion beam is then used to remove materials from the surface at high lateral resolution and cut through the whisker with an accuracy better than 10 nm.

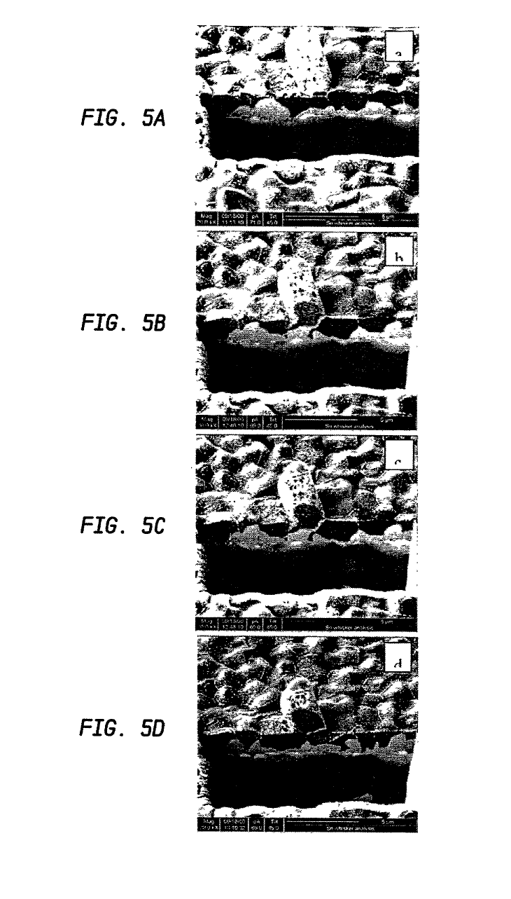

FIGS. 5A-5D show FIB images of a whisker found on a matte Sn surface, which was plated directly on a Cu substrate. The sample was aged at room temperature for 13 months. The images represent various stages of cutting through the whisker. FIG. 5A is the FIB image of the surface taken after a trench is cut into the coating next to the whisker. FIB is then used to gradually cut through the whisker and FIB images were taken at various stages of cutting. These results are shown in FIGS. 5B, 5C and 5D. The grain structure around the whisker is revealed in these images.

Three different layers can be identified in these images: Cu substrate, Sn—Cu intermetallic layer and Sn layer. The intermetallic growth at the Sn and Cu interface shows strong anisotropy, with some areas growing much faster than others. There are also a very clear grain boundary between the whisker and adjacent grains. The whiskers seem to originate from the middle of the Sn coating, rather than from the Sn—Cu interface or the Sn surface. Apparently, a whisker nucleus is formed within the Sn coating and then grows out of the Sn coating.

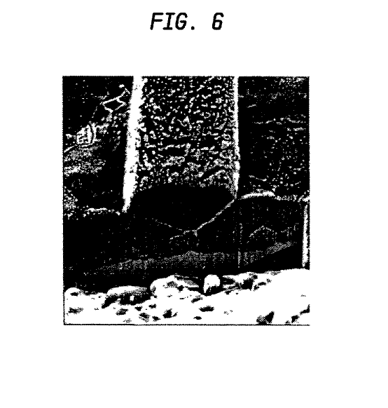

Very similar results have been also obtained for satin bright Sn plated on Cu substrate. FIG. 6 shows a FIB image for a whisker found on the satin bright Sn, which was aged at room temperature for 18 months. Here again, intermetallic compound formation is observed at Sn and Cu interface. Similar to the matte Sn, very clear grain boundary is observed between the whisker and adjacent grains and the whisker is originated within Sn film. It is also noteworthy that in both cases the whisker is sitting on top of the intermetallic phase.

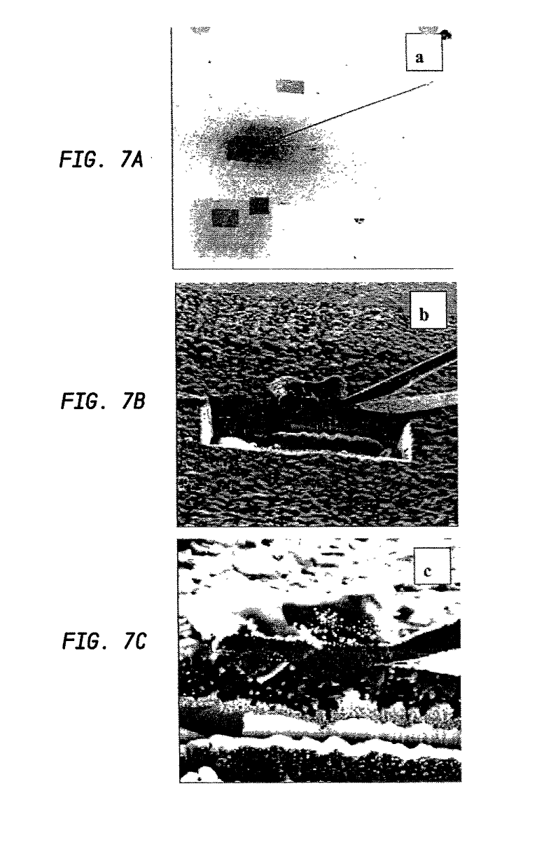

FIB experiments were also performed on bright Sn, which was plated over the Cu substrate. The sample was aged at room temperature for 18 months. FIGS. 7A-7C show FIB images with increasing magnification. The length of this particular whisker is about 250 μm. The long filament-type whisker originates from the nodule on the surface. There is again a very clear grain boundary between the filament whisker and nodule whisker. The filament is not in direct contact with the Sn coating. The mass transport from Sn film to the filament whisker, necessary for the formation of this very long whisker, occurs through the nodule whisker. The nodule whisker apparently acts as a precursor state for the formation of the filament whisker. This is consistent with the observation that the nodule whisker is seen before the filament whisker during the aging at room temperature as well as 50° C.

In all three cases, no grain boundary migration is observed within the Sn coating. Sn atoms seem to be pumped into the whisker through a localized grain boundary. These results would suggest again that the compressive stress promotes whisker growth and tensile stress hinders whisker growth.

Internal stress in the bright sn coating was also measured using x-ray diffraction (XRD). In a XRD experiment, the change of the lattice constant due to the stress is measured. The stress can then be calculated from this measurement. The real-time analysis of stress evaluation during the aging can also be performed. The stress measurement results are summarized in Table 2. Measurements were performed both along the rolling direction as well as perpendicular to the rolling direction. As Table 2 demonstrates, both directions show virtually identical stress, indicating an isotropic biaxial stress in the Sn coating. No shear stress was observed on any samples. The as-plated bright Sn coating on Cu shows compressive stress of about 5 MPa. The same sample after aging for 15 months at room temperature shows a much higher compressive stress. The increase of the stress during the aging is most likely related to the intermetallic formation. The diffusion of Cu into the Sn coating occupies more space and generates compressive stress in the Sn-coating. The built-up of compressive stress during the aging explains the incubation time observed for the whisker growth on bright Sn. The presence of a Ni-underlayer minimizes or even eliminates the diffusion of Cu into Sn and Sn—Cu intermetallic formation. As a result of that, no compressive stress is observed on Sn/Ni/Cu. Instead, a tensile stress is observed for this sample. Consistent with this result, no whiskers are observed on these samples.

TABLE 2
Internal Stress measured by XRD

| | | | | | Perpendicular to | |
|---|---|---|---|---|---|---|
| | Aging Time | | Rolling Directions | | Rolling Directions | |
| Sn/Cu | As plated | | −4 ± 1 | MPa | −5 ± 2 | MPa |
| Sn/Cu | 15 | Months | −13 ± 2 | MPa | −14 ± 1 | MPa |
| Sn/Ni/Cu | 3 | months | 14 ± 1 | MPa | 12 ± 1 | MPa |

It is to be understood that the above-described embodiments are illustrative of only a few of the many possible specific embodiments which can represent applications of the principles of the invention. Numerous and varied other arrangements can be readily devised by those skilled in the art without departing from the spirit and scope of the invention.

What is claimed is:

1. A coated metal article comprising:
a metal substrate;
overlying the substrate a surface finish comprising a layer of tin or tin alloy being in a tensile stress state.

2. A coated metal article of claim 1 wherein the layer of tin or tin alloy has an average grain size in excess of about 1 micrometer.

3. A coated metal article of claim 1 wherein the average tensile stress is in excess of about 2 MPa.

4. The coated metal article of claim 1 further comprising an underlayer of nickel, nickel alloy, cobalt, cobalt alloy, iron or iron alloy chosen to generate or maintain tensile stress in the layer of tin or tin alloy above the underlayer.

5. The coated metal article of claim 1 wherein the tin or tin alloy layer has a thickness in the range 0.5 to 10 micrometers.

6. The coated metal article of claim 4 wherein the underlayer has a thickness in the range 0-20 micrometers.

7. A method of inspecting or monitoring an article having a coating of tin or tin alloy for tendency to grow tin whiskers comprising the steps of:
determining the internal stress in the coating; and
accepting or rejecting the article based on whether the internal stress comprises tensile stress exceeding a specified value.

8. The method of claim 7 wherein the internal stress is determined by using x-ray diffraction to measure the change in the lattice constant in the coating due to stress.

9. The method of claim 7 wherein articles with coatings having tensile stress in excess of about 2 MPa are accepted.

10. The method of claim 7 wherein articles with coatings having tensile stress in excess of about 3 MPa are accepted.
